(19) United States
(12) Patent Application Publication
(10) Pub. No.: US 2026/0354133 A1
(43) Pub. Date: Nov. 5, 2026

(54) LASER ANNEALING METHOD AND METHOD FOR MANUFACTURING SEMICONDUCTOR DEVICE BY USING SAME

(71) Applicant: RNR LAB INC., Yongin-si, Gyeonggi-do (KR)

(72) Inventors: Jeong Do RYU, Seoul (KR); Joo Hyun CHO, Yeongin-si, Gyeonggi-do (KR); Jeong Hyun RYU, Hanam-si, Gyeonggi-do (KR); Sung Hoon RYU, Yangyang-gun, Gangwon-do (KR); Sung Ho KANG, Hwaseong-si, Gyeonggi-do (KR)

(73) Assignee: RNR LAB INC., Yongin-si, Gyeonggi-do (KR)

(21) Appl. No.: 19/485,673

(22) PCT Filed: Apr. 22, 2024
(86) PCT No.: PCT/KR2024/005398

§ 371 Date: Nov. 19, 2025

(30) Foreign Application Priority Data
May 24, 2023 (KR) 10-2023-0067071

(51) Int. Cl. H10P 95/90; H10D 30/01; H10D 64/01

(52) U.S. Cl. CPC H10P 95/90; H10D 30/021; H10D 64/011; H10D 64/01338

(57) ABSTRACT

A laser annealing method and a method for manufacturing a semiconductor device applying the same are disclosed. The disclosed laser annealing method for a semiconductor device part comprising a transistor comprises the steps of preparing a semiconductor device part having a transistor comprising a semiconductor and a dielectric forming a junction interface with the semiconductor, and passivating at least interface charges between the semiconductor and the dielectric in a gas atmosphere of at least one of deuterium (D₂), hydrogen (H₂), and ammonia (NH₃), and performing laser annealing by irradiating the semiconductor element with a laser under pressure conditions higher than 1 atmosphere in a gaseous atmosphere of at least one of hydrogen (H₂) and ammonia (NH₃).

### TECHNICAL FIELD

The present invention relates to an annealing method for a workpiece and a manufacturing method for a device applied thereto, and more particularly to a laser annealing method and a manufacturing method for a semiconductor device applied thereto.

### BACKGROUND ART

A metal-oxide-semiconductor field effect transistor (MOSFET) is a device that regulates the amount of current flowing between a source and a drain by the voltage applied to its gate. Since its development in the 1960s, MOSFETs have been used throughout industry and have been a major breakthrough in technological advancement. MOSFETs are used as the core device in integrated circuits, and most semiconductor devices produced in mass quantities today are based on MOSFETs. With the advancement of semiconductor technology, the integration and performance of unit transistor devices such as MOSFETs have been continuously improved. In addition, new (or modified) structures of FET devices are being developed that may overcome the problems and performance limitations associated with high integration (i.e., scaling down) of conventional MOSFETs.

In the manufacture of transistor devices such as MOSFETs, thermal treatment processes are used that may deactivate the interfacial charges present at the interface between the gate dielectric layer and the semiconductor channel, thereby reducing the density of effective interfacial charges. These heat treatment processes may improve the film quality of the gate dielectric layer, which in turn may improve the performance and reliability of the transistor.

However, since the conventional heat treatment process consists of heating the substrate under a forming gas atmosphere, it requires a relatively long processing time and is difficult to perform efficiently. In addition, even if the dangling bonds present at the interface between the gate dielectric layer and the semiconductor channel are deactivated by the conventional heat treatment process, the defects may be reactivated by the reactivation phenomenon. These problems may occur not only at the interface, but also within the gate dielectric layer.

Therefore, in the manufacture of transistor devices such as MOSFETs, it is necessary to develop technologies that may overcome the above-mentioned existing problems and limitations and efficiently improve the performance and reliability of transistors. In addition, as the integration density of transistors is greatly improved and their shapes, structures, and scales are modified or developed, it is necessary to develop technologies and processes to secure performance and reliability.

### DISCLOSURE OF THE INVENTION

### Technical Problem

The technical problem of the present invention is to provide a process technology (laser annealing method) for manufacturing semiconductor devices including transistors, which may efficiently passivate interface charges between a semiconductor and a dielectric while significantly improving the performance, stability, and reliability of the transistors.

Furthermore, the technical challenge of the present invention is to provide a method for manufacturing a semiconductor device using the above process technology (laser annealing method).

The problems that the present invention is intended to solve are not limited to those mentioned above, and other problems not mentioned will be understood by those skilled in the art from the following description.

### Technical Solution

According to one embodiment of the present invention, a method of laser annealing a semiconductor device comprising a transistor, comprising: preparing a semiconductor device having a transistor comprising a semiconductor and a dielectric forming a junction interface with the semiconductor; and irradiating the semiconductor device with a laser to perform laser annealing under pressure conditions greater than 1 atm in a gaseous atmosphere of at least one of deuterium (D₂), hydrogen (H₂), and ammonia (NH₃), in order to passivate interface charges between the semiconductor and the dielectric.

The pressure condition may be equal to or less than 100 atmospheres.

The pressure condition may be greater than 1 atmosphere and less than 100 atmospheres.

The transistor may be formed on a substrate, and the laser annealing may be performed while a temperature of the substrate is controlled in a range from about room temperature to about 550° C.

The laser annealing may be performed in a deuterium (D₂) gas atmosphere.

The laser annealing may be performed such that a temperature of a surface portion of the semiconductor device is raised from about 600° C. to 2000° C.

The laser annealing may be performed for about 0.01 μs to 10 seconds.

The semiconductor may comprise a channel of the transistor, and the dielectric may comprise a gate dielectric layer of the transistor.

The step of preparing the semiconductor device may comprise forming a wiring member electrically connected to the transistor, and before or after the step of forming the wiring member, the laser annealing may be performed.

The laser may comprise any one of ultraviolet ray, visible ray, infrared ray, and microwave.

According to another embodiment of the present invention, there is provided a method of manufacturing a semiconductor device applying the aforementioned laser annealing method.

### Advantageous Effects

According to embodiments of the present invention, in the manufacture of a semiconductor device including a transistor, a process technology (laser annealing method) may be implemented that may efficiently passivate an interfacial charge between a semiconductor and a dielectric while significantly improving the performance, stability, and reliability of the transistor. According to one embodiment, by performing a high-speed annealing process using laser irradiation in a gas atmosphere such as deuterium (D₂), which has a high binding energy to a semiconductor element (e.g., silicon), while forming a pressurized condition higher than 1 atm, a passivation process to remove interfacial charges may be efficiently performed, and the performance, stability, and reliability of a semiconductor device may be greatly improved. Furthermore, the process technology (laser annealing method) according to embodiments of the present invention may be useful in the manufacture of highly integrated semiconductor devices.

By applying the laser annealing method according to embodiments of the present invention, it may be possible to manufacture semiconductor devices having high integration while having excellent performance, stability, and reliability.

However, the effects of the present invention are not limited to the above effects, and may be expanded in various ways without departing from the technical ideas and scope of the present invention.

### BRIEF DESCRIPTION OF THE DRAWINGS

FIGS. 1a to 1c are cross-sectional views to illustrate a laser annealing method for a semiconductor device including a transistor, in accordance with one embodiment of the present invention.

FIGS. 2a and 2b are cross-sectional views to illustrate a laser annealing method for a semiconductor device including a transistor, according to another embodiment of the present invention.

FIGS. 3a through 3d are cross-sectional views to illustrate a laser annealing method for a semiconductor device comprising a transistor, according to another embodiment of the present invention.

FIG. 4 is a plan view illustrating an exemplary form of pattern that the plurality of nanodots comprising the heating layer described in FIGS. 3a and 3b may have.

### BEST MODE FOR CARRYING OUT THE INVENTION

Embodiments of the present invention will now be described in detail with reference to the accompanying drawings.

The embodiments of the invention described below are provided to make the invention more apparent to those of ordinary skill in the art, and the scope of the invention is not limited by the following embodiments, which may be modified in various other ways.

The terms used in this specification are intended to describe particular embodiments and are not intended to limit the invention. Terms used herein in the singular form may include the plural form, unless the context clearly indicates otherwise. Furthermore, the terms “comprise” and/or “comprising” as used herein are intended to specify the presence of the mentioned shapes, steps, numbers, motions, absences, elements, and/or groups thereof, and are not intended to exclude the presence or addition of one or more other shapes, steps, numbers, motions, absences, elements, and/or groups thereof. Further, as used herein, the term “connected” is intended to mean not only that certain elements are directly connected, but also that they are indirectly connected by the interposition of other elements between them.

Further, when the present disclosure refers to a member being located “on” another member, this includes not only when a member is abutting another member, but also when there is another member between the two members. As used herein, the term “and/or” includes any one of the enumerated items and any combination of one or more of them. In addition, the terms “about,” “substantially,” and the like as used in the disclosure are intended to mean at or near the range of numbers or degrees, taking into account inherent manufacturing and material tolerances, and to prevent infringers from taking unfair advantage of the disclosure where precise or absolute numbers are stated, which are provided for the purpose of illustration.

Embodiments of the present invention will now be described in detail with reference to the accompanying drawings. The sizes or thicknesses of the areas or parts shown in the accompanying drawings may be somewhat exaggerated for clarity and ease of description. Throughout the detailed description, like reference numerals denote like components.

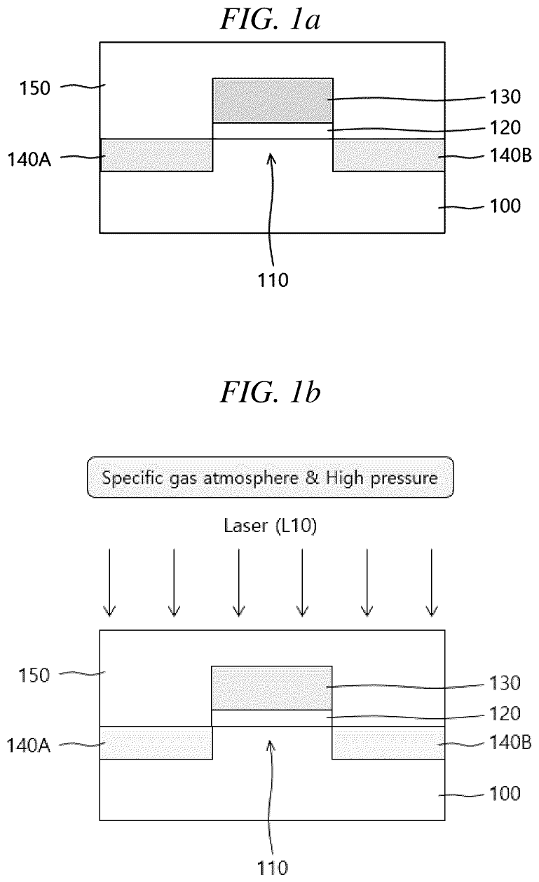

FIGS. 1a through 1c are cross-sectional views to illustrate a laser annealing method for a semiconductor device including a transistor, in accordance with one embodiment of the present invention.

Referring to FIG. 1a, a laser annealing method according to one embodiment of the present invention may include the step of preparing a semiconductor device having a transistor. The transistor may include a semiconductor and a dielectric forming a junction interface with the semiconductor.

According to an example, the semiconductor may include or correspond to the channel portion 110 of the transistor, and the dielectric may include or correspond to the gate dielectric layer 120 of the transistor. According to a specific embodiment, the transistor may comprise a channel portion 110 composed of a semiconductor material and a gate dielectric layer 120 bonded to the channel portion 110. The gate dielectric layer 120 may be disposed on the channel portion 110, and a gate electrode 130 may be disposed on the gate dielectric layer 120. The channel portion 110 may be provided with a source 140A electrically connected to or in contact with a first region (e.g., a first end) of the channel portion 110, and a drain 140B electrically connected to or in contact with a second region (e.g., a second end) of the channel portion 110. The channel portion 110 may be referred to as a channel member or channel region. The source 140A may be referred to as a source member or source region, and similarly, the drain 140B may be referred to as a drain member or drain region.

In one example, the transistor may be formed on a predetermined substrate 100. The channel portion 110 and the source 140A and drain 140B may be defined or formed within a surface portion of the substrate 100. The channel portion 110 may be defined between the source 140A and the drain 140B. The source 140A and drain 140B may be regions that are doped (ion implanted) with a high concentration of conductive impurities.

The substrate 100 may be, as a non-limiting example, a silicon (Si) substrate, a germanium (Ge) substrate, or a IV intergroup compound substrate such as a silicon (Si)-germanium (Ge) substrate, or a III-V or II-VI intergroup compound substrate, and may be a semiconductor substrate having a stacked structure such as a silicon-on-insulator (SOI) to suppress body effects, or a semiconductor layer obtained through epitaxial growth. The substrate 100 may be provided with insulating regions such as shallow trench isolation (STI) to define active regions, and well regions may be formed with conductive shapes suitable for implementing n-type metal-oxide-semiconductor (NMOS) transistors or p-type metal-oxide-semiconductor (PMOS) transistors.

The channel portion 110 may comprise, as a non-limiting example, silicon (Si), germanium (Ge), or a IV intergroup compound such as silicon (Si)-germanium (Ge), or may comprise a III-V intergroup compound or a II-VI intergroup compound.

The gate dielectric layer 120 may comprise, for example, silicon oxide (e.g., SiO₂), silicon oxynitride (e.g., SiON), or silicon nitride (e.g., Si₃N₄), or may comprise a high-k material having a higher dielectric constant than silicon nitride. The gate dielectric layer 120 may also include a stacked structure comprising two or more layers of different dielectric materials. Any material that may be used as a gate dielectric (insulating) material in a typical transistor device may be applied as a material in the gate dielectric layer 120. The gate dielectric layer 120 may be referred to as a gate insulating layer.

The gate electrode 130 may be formed of any predetermined conductive material, such as impurity doped conductive polysilicon, metal, or metal compound, and may be tuned to have a suitable work function. Although not shown, sidewall insulating layers may further be formed on both walls of the gate laminate comprising the gate dielectric layer 120 and the gate electrode 130.

The semiconductor device may further include an insulating layer 150 formed to cover the gate electrode 130 on the substrate 100. The insulating layer 150 may be formed to cover the source 140A, drain 140B and the gate electrode 130. After depositing a predetermined layer of insulating material, a planarization process may be performed on the top surface thereof to form the insulating layer 150. The insulating layer 150 may comprise one or more insulating materials, including, as a non-limiting example, silicon oxide (e.g., SiO₂), silicon oxide nitride (e.g., SiON), or silicon nitride (e.g., Si₃N₄), or may comprise other insulating materials. The insulating layer 150 may be referred to as an interlayer insulating film.

Referring to FIG. 1b, a laser annealing method according to an embodiment of the present invention may comprise the step of performing laser annealing (i.e., laser heat treatment) by irradiating the semiconductor element with a laser (L10) under pressure conditions higher than 1 atm in a gaseous atmosphere of at least one of deuterium (D₂), hydrogen (H₂), and ammonia (NH₃). The laser annealing may be performed by irradiating the semiconductor element with a laser (L10) under a pressure higher than 1 atm with a gas atmosphere in the chamber, wherein the semiconductor element is placed in a predetermined chamber. The laser annealing may be for passivation of at least interface charges between the semiconductor and the dielectric. In this embodiment, the semiconductor may be a channel portion 110, and the dielectric may be a gate dielectric layer 120.

The gas used to create the gas atmosphere may comprise elements for passivating at least the interfacial charge between the semiconductor and the top dielectric, i.e., the interfacial charge between the channel portion 110 and the gate dielectric layer 120. According to one example, by the heat treatment process by laser annealing described above, the elements in the gas may play a role in deactivating (i.e., passivating) the interfacial charge generated by the dangling bond or the like by forming Si-D bonding or Si—H bonding or the like at or around the junction interface between the channel portion 110 and the gate dielectric layer 120. At this time, not only the above interfacial charges but also the fixed charges existing around the above interfaces may be deactivated (passivated) by a principle similar to the above. Thus, the interfacial properties between the channel portion 110 and the gate dielectric layer 120 and the properties of the gate dielectric layer 120 may be improved, and consequently, the performance, stability, and reliability of the transistor device may be improved.

In particular, the use of deuterium in the gas atmosphere may further improve the stability and reliability of the transistor device because deuterium has a higher bonding energy with semiconductors such as silicon than hydrogen. For example, since more energy is required to break the Si-D bond than the Si—H bond, the use of deuterium may be more effective in reducing the trap level at the junction interface and in performing the passivation process. In this respect, it may be preferable to perform the laser annealing in a deuterium (D₂) gas atmosphere. The laser annealing may be performed in a 100% deuterium (D₂) gas atmosphere, or in a gas atmosphere comprising about 10% or more or about 40% or more deuterium (D₂). However, in some cases, other passivation gases other than deuterium (D₂) gas may be used, such as hydrogen (H₂) gas or ammonia (NH₃) gas.

The pressure formed within the chamber in the laser annealing may be greater than 1 atmosphere (760 Torr). For example, the pressure may be greater than or equal to 1 atmosphere and less than or equal to 100 atmospheres. More preferably, the pressure may be greater than or equal to 3 atm and less than or equal to 100 atm, or greater than or equal to 3 atm and less than or equal to 50 atm. By creating relatively high pressure conditions during the above laser annealing, the elements of the gas (passivation gas) may be made to bond better with semiconductor elements such as silicon, i.e., by using relatively high pressure conditions, the elements of the gas (passivation gas) may be made to bond better with semiconductor elements such as silicon at the interface between the channel portion 110 and the gate dielectric layer 120 and in the region surrounding thereof. In particular, if the gas includes deuterium, the bond-promoting effect (inter-element bond-promoting effect) by high pressure may be further enhanced. Furthermore, if the pressure is about 3 atmospheres or more, the effect of promoting inter-elemental bonding may be improved.

The laser L10 used in the laser annealing may be a laser (laser beam) generated from any one of, for example, a yttrium aluminum garnet (YAG) laser generator, a CO₂ laser generator, a diode laser generator, and a fiber laser generator. The laser L10 may comprise any one of ultraviolet ray, visible ray, infrared ray, and microwave. The laser L10 may have a wavelength of, for example, about 0.02 μm to 11 μm.

In the laser annealing, the laser L10 may be irradiated from the top of the semiconductor element part to the surface of the insulating layer 150. The laser annealing may be performed such that the temperature of the surface portion of the semiconductor element is raised to about 600° C. to 2000° C. By utilizing the laser L10, the temperature of the surface portion of the semiconductor element may be raised to a substantially higher temperature within a short period of time, and the heat treatment process for passivation described above may be performed efficiently and easily. In particular, by promoting the penetration and bonding of elements by instantaneous heating and pressurization by laser irradiation, the process of deactivating interfacial charges and fixed charges may be efficiently and effectively carried out in a short time.

The laser annealing may be performed for, for example, from about 0.01 to 10 seconds. More preferably, the laser annealing may be performed for about 0.1 to 1 second. However, the time range of the laser annealing is not limited to the foregoing and may be varied in some cases.

According to one embodiment of the present invention, the laser annealing may be performed while the temperature of the substrate 100 is controlled to range from room temperature (e.g., about 25° C.) to about 550° C. As a more specific example, the laser annealing may be performed while the temperature of the substrate 100 is controlled to range from about room temperature to about 550° C., or from about 350° C. to about 450° C. If the laser annealing is performed while the substrate 100 is heated to a predetermined temperature, the passivation of the interfacial charges may be more efficient. However, if the temperature of the substrate 100 is higher than about 550° C. or higher than about 450° C., there is a possibility that unwanted reactions that degrade the characteristics of the transistor may occur in a portion of the substrate 100. Accordingly, it may be desirable that the heating temperature of the substrate 100 is below about 550° C. or below about 450° C.

Referring to FIG. 1c, a wiring member 200 may be formed on the insulating layer 150. The wiring member 200 may be a member electrically connected to the transistor. For example, the wiring member 200 may be formed to be electrically connected with the gate electrode 130. Although a single wiring member 200 is shown here, a plurality of wiring members may be formed. There may be a wiring member electrically connected to the source 140A, and there may be a further wiring member electrically connected to the drain 140B. The wiring member 200 may be viewed as a component included in the transistor.

The wiring member 200 may comprise at least one of a metal and a metal compound. Thus, the process of forming the wiring member 200 may be referred to as a type of metallization process. Typical electrodes, contact layers, and wiring materials used in semiconductor processes may be applied to the wiring member 200. The wiring member 200 does not necessarily have to be in the form of a line, and may be of any shape. The wiring member 200 may be referred to as a metallic member or metallic wiring comprising a metal or metal compound.

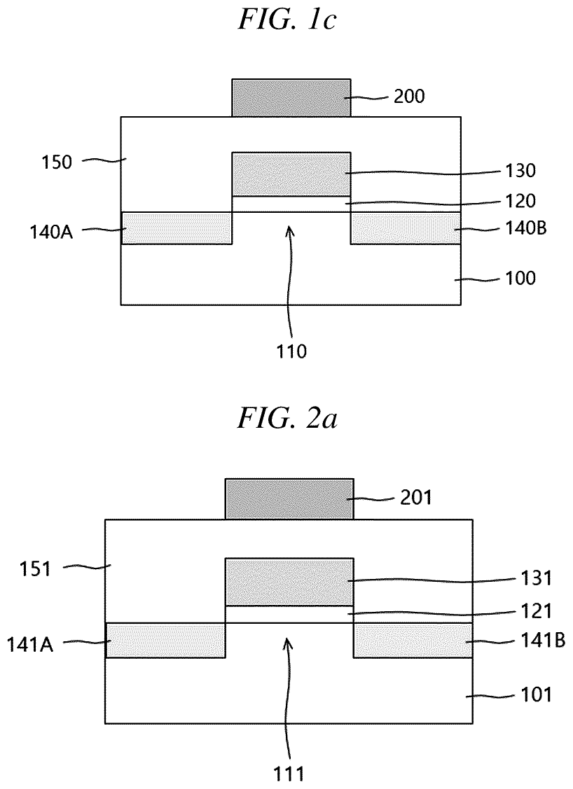

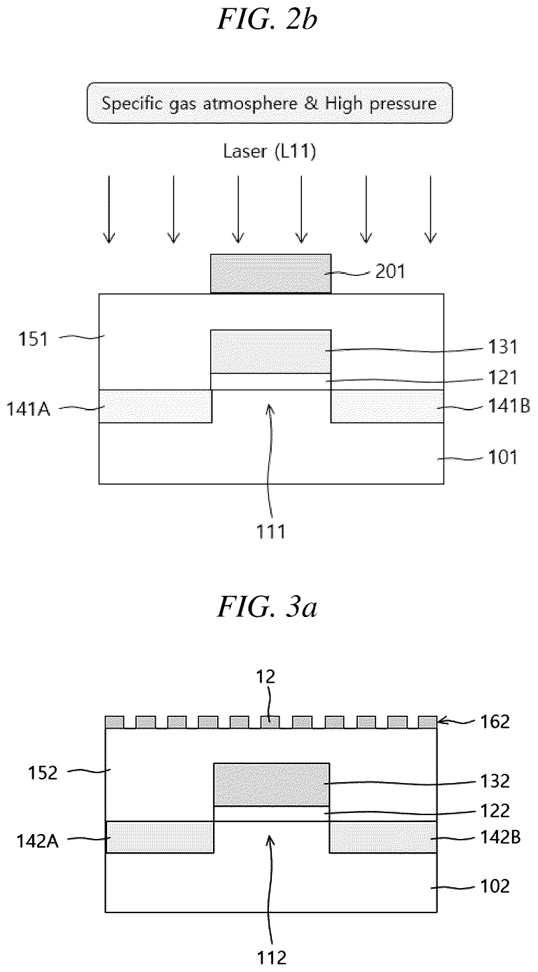

While the embodiments of FIGS. 1a to 1c describe performing the laser annealing process before performing the metallization process, according to other embodiments of the present invention, the laser annealing process may be performed after performing the metallization process. These other embodiments will be described with reference to FIG. 2a and FIG. 2b.

FIGS. 2a and 2b are cross-sectional views to illustrate a laser annealing method for a semiconductor device including a transistor, according to another embodiment of the present invention.

Referring to FIG. 2a, a laser annealing method according to an embodiment of the present invention may include the step of preparing a semiconductor device having a transistor. The semiconductor device of FIG. 2a may include the configuration of the transistor described in FIG. 1a, i.e., the semiconductor device of FIG. 2a may include a substrate 101, a channel portion 111, a gate dielectric layer 121, a gate electrode 131, a source 141a, a drain 141b, and an insulating layer 151. The substrate 101, channel portion 111, gate dielectric layer 121, gate electrode 131, source 141a, drain 141b, and insulating layer 151 may correspond to the substrate 100, channel portion 110, gate dielectric layer 120, gate electrode 130, source 140A, drain 140B, and insulating layer 150 of FIG. 1a, respectively.

In this embodiment, a wiring member 201 may be formed by a metallization process on the insulating layer 151 before performing laser annealing. The wiring member 201 may be the same or similar to the wiring member 200 described in FIG. 1c.

Referring to FIG. 2b, a laser annealing method according to this embodiment may comprise the step of irradiating the semiconductor element with a laser (L11) to perform laser annealing (i.e., laser heat treatment) under a pressure higher than 1 atm in a gaseous atmosphere of at least one of deuterium (D₂), hydrogen (H₂), and ammonia (NH₃). The laser annealing may be performed by irradiating the semiconductor element with a laser (L11) under the condition of placing the semiconductor element in a predetermined chamber and creating a pressure higher than 1 atmosphere in the chamber with the gas atmosphere. The laser annealing may be for passivation of at least interface charges between the semiconductor and the dielectric. The semiconductor may be a channel portion 111, and the dielectric may be a gate dielectric layer 121.

The specific conditions, features, effects, etc. of the laser annealing may be similar to those described with reference to FIG. 1b. The pressure condition may be a condition of about 100 atmospheres or less. More preferably, the pressure condition may be a condition of about 1 atmosphere above and below 100 atmospheres, or a condition of about 3 atmospheres above and below 100 atmospheres. The laser annealing may preferably be performed in an inert gas atmosphere comprising deuterium (D₂). The laser annealing may be performed such that the temperature of the surface portion of the semiconductor element is raised from about 600° C. to 2000° C. The laser annealing may be performed for, for example, from about 0.01 μs to 10 seconds. The laser may comprise any one of ultraviolet ray, visible (visible ray), infrared ray, and microwave. The laser annealing may be performed while the temperature of the substrate 101 is controlled to range from about room temperature to about 550° C. For example, the laser annealing may be performed with the temperature of the substrate 101 controlled to range from about room temperature to about 550° C. In addition, specific conditions, features, effects, etc. of the above laser annealing may be described with reference to FIG. 1b.

According to an example, the temperature at which the surface portion of the semiconductor element part is heated by the laser annealing in the present embodiment may be lower than the temperature at which the surface portion of the semiconductor element part is heated by laser annealing in the embodiment of FIG. 1b. When the laser annealing is performed while the wiring member 201 is formed, the heating temperature of the surface portion may be adjusted so that the wiring member 201 is not damaged by the laser annealing. Furthermore, it may be desirable to form the wiring member 201 with a metal or metal compound having a relatively high melting point.

In the embodiment described with reference to FIGS. 2a and 2b, since the laser annealing is performed while the wiring member 201 is pre-formed to passivate the interfacial charge between the channel portion 111 and the gate dielectric layer 121, the interfacial region between the channel portion 111 and the gate dielectric layer 121 may not be affected by the process for forming the wiring member 201 after the passivation.

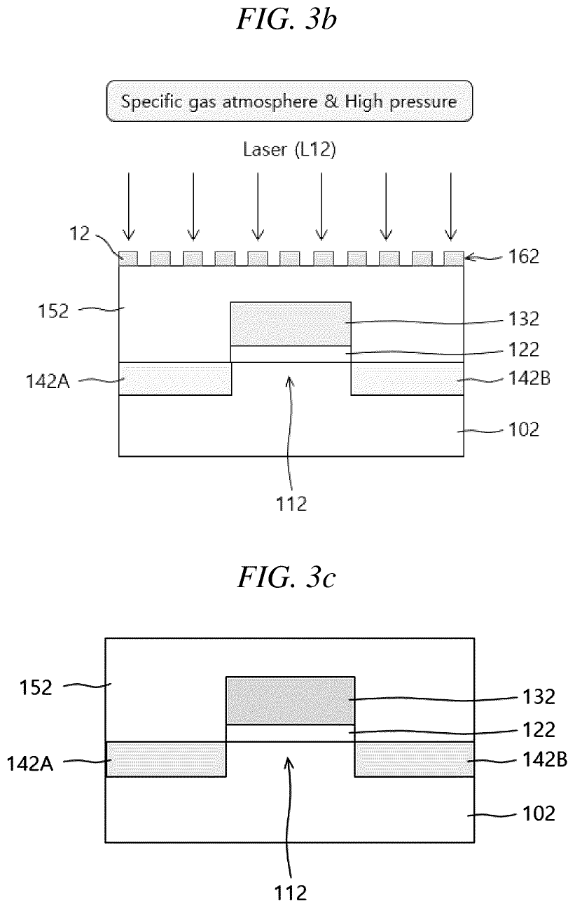

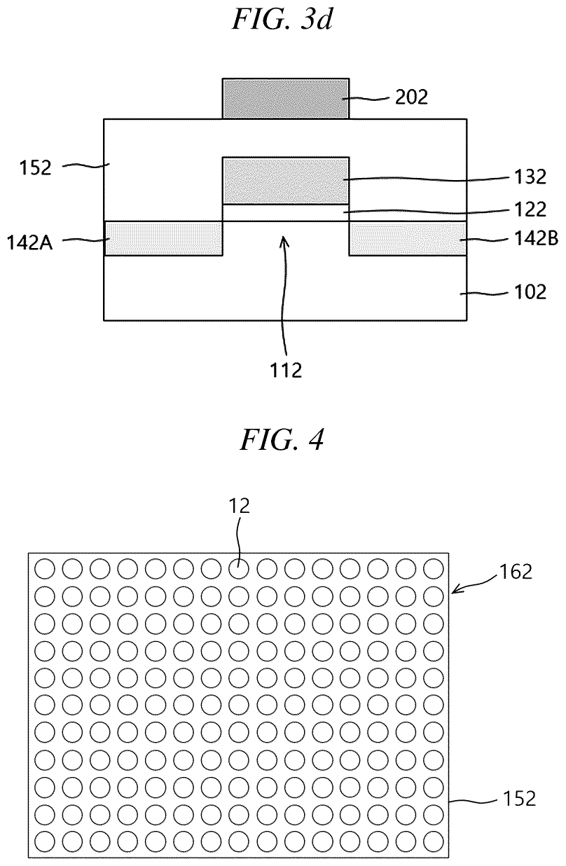

FIGS. 3a to 3d are cross-sectional views to illustrate a laser annealing method for a semiconductor device including a transistor, in accordance with another embodiment of the present invention.

Referring to FIG. 3a, a laser annealing method according to an embodiment of the present invention may include the step of preparing a semiconductor device having a transistor. The semiconductor device of FIG. 3a may include the configuration of the transistor described in FIG. 1a, i.e., the semiconductor device of FIG. 3a may include a substrate 102, a channel portion 112, a gate dielectric layer 122, a gate electrode 132, a source 142a, a drain 142b, and an insulating layer 152. The substrate 102, channel portion 112, gate dielectric layer 122, gate electrode 132, source 142a, drain 142b, and insulating layer 152 may correspond to the substrate 100, channel portion 110, gate dielectric layer 120, gate electrode 130, source 140A, drain 140B, and insulating layer 150 of FIG. 1a, respectively.

In this embodiment, a heating layer 162 may be formed on the insulating layer 152 prior to performing the laser annealing. The heating layer 162 may include at least one of a metal and a metal compound. For example, the heating layer 162 may include at least one of TiN, Ti, TiSi, Ta, TaN, Co, CoSi, Ni, NiSi, Ru, W, WSi, Cu, Re, Mo, Nb, and Cr. The heating layer 162 may preferably have a thickness of about 30 Å to 4000 Å to enhance its functionality, but the present embodiment is not limited thereto, and the suitable thickness of the heating layer 162 may be varied in some cases. The heating layer 162 may have a relatively high absorption rate for the laser, and may act to transfer or trap heat toward the insulating layer 152. In this regard, the heating layer 162 may be referred to as a “laser absorbing layer” or “heat transfer layer”.

According to one embodiment, the heating layer 162 may have a nano pattern structure or a nano dot array structure. For example, the heating layer 162 may comprise a nano dot array including a plurality of nano dots 12. The plurality of nano dots 12 may be formed of a metallic material, such as a metal or a metal compound. When the heating layer 162 has a nano dot array structure, the heating layer 162 may effectively serve to absorb the laser and transfer heat during the subsequent laser annealing step while effectively allowing the gas to pass through. However, in some cases, the heating layer 162 may not have a nano dot array structure, and may have a continuous layer structure. If the heating layer 162 has a continuous layer structure, the gas permeation properties may be tuned by appropriately controlling its thickness.

Referring to FIG. 3b, a laser annealing method according to this embodiment may comprise the step of irradiating the semiconductor element with a laser (L12) to perform laser annealing (i.e., laser heat treatment) under pressure conditions higher than 1 atm in a gaseous atmosphere of at least one of deuterium (D₂), hydrogen (H₂), and ammonia (NH₃). The laser annealing may be performed by irradiating the semiconductor element with a laser (L12) under a pressure higher than 1 atm with a gas atmosphere in the chamber, wherein the semiconductor element is placed in a predetermined chamber. The laser annealing may be for passivation of at least interface charges between the semiconductor and the dielectric. The semiconductor may be a channel portion 112, and the dielectric may be a gate dielectric layer 122.

The specific conditions, features, effects, etc. of the laser annealing may be the same or similar to those described with reference to FIG. 1b. The pressure condition may be a condition of about 100 atmospheres or less. More preferably, the pressure condition may be a condition of about 1 atm greater than or equal to 100 atm but less than or equal to 100 atm, or a condition of about 3 atm greater than or equal to 100 atm. The laser annealing may preferably be performed in an inert gas atmosphere comprising deuterium (D₂). The laser annealing may be performed such that the temperature of the surface portion of the semiconductor element is raised from about 600° C. to 2000° C. The laser annealing may be performed for, for example, from about 0.01 μs to 10 seconds. The laser may comprise any one of ultraviolet ray, visible ray, infrared ray, and microwave. The laser annealing may be performed while the temperature of the substrate 102 is controlled to range from about room temperature to about 550° C. For example, the laser annealing may be performed with the temperature of the substrate 102 controlled to range from about room temperature to about 550° C. In addition, specific conditions, features, effects, etc. of the above laser annealing may be described with reference to FIG. 1b.

After the steps of FIG. 3b, the heating layer 162 may be removed. The resulting product is shown in FIG. 3c.

Referring to FIG. 3d, a wiring member 202 may be formed on the insulating layer 152 by a metallization process. The wiring member 202 may be the same or similar to the wiring member 200 described in FIG. 1c.

FIG. 4 is a plan view illustrating an exemplary shape of a pattern that the plurality of nanodots comprising the heating layer 162 described in FIGS. 3a and 3b may have.

Referring to FIG. 4, by appropriately controlling the dimensions of the plurality of nanodots 12 and the spacing between them, the heating layer 162 comprising them may serve to have a discontinuous layer structure, which facilitates the absorption of thermal energy by the laser while effectively allowing the penetration of gas. In this regard, the diameter of the plurality of nanodots 12 may preferably be on the order of about 5 nm to 10³ nm, and the spacing between the plurality of nanodots 12 may preferably be on the order of about 5 nm to 10² nm. However, the range of suitable diameters and spacing of the plurality of nanodots 12 may vary depending on, for example, the wavelength of the laser used. Further, the arrangement of the plurality of nanodots 12 is not limited to that shown in FIG. 4, but may be varied. Furthermore, the heating layer 162 may have a variety of nanopattern shapes other than a nanodot array structure, and in some cases, may have a continuous layer shape.

While the “transistors” described in the foregoing embodiments may have a MOSFET structure, they may have a variety of other transistor structures. For example, the transistor may have a gate-all-around (GAA) FET structure, a fin FET structure, a tunneling FET structure, a spin FET structure, a recess transistor structure, or any other transistor structure. Further, the “transistor” described in the foregoing embodiments may be a transistor as a general switching or driving element, or in some cases, a memory transistor. When the transistor is a memory transistor, for example, a tunnel insulation layer (dielectric layer), a charge storage layer (charge trap layer), and a blocking insulation layer may be disposed between the semiconductor channel and the gate electrode (control gate electrode). In this case, the laser annealing process may be a process for improving the performance, stability, and reliability of the device by passivating at least the interfacial charge between the semiconductor channel and the tunnel insulating layer (dielectric layer). The term transistor as used herein may be interpreted broadly.

According to an embodiment of the present invention, there is provided a method for manufacturing a semiconductor device by applying the aforementioned laser annealing method. Here, the semiconductor device may be a memory device or a non-memory device. The semiconductor device may comprise various electronic devices.

According to the embodiments of the present invention described above, in the manufacture of a semiconductor device including a transistor, a process technology (laser annealing method) may be implemented that may efficiently passivate an interfacial charge between a semiconductor and a dielectric while significantly improving the performance, stability, and reliability of the transistor. According to one embodiment, by performing a high-speed annealing process using laser irradiation in a gas atmosphere such as deuterium (D₂), which has a high binding energy to a semiconductor element (e.g., silicon), while forming a pressure condition higher than 1 atmosphere, a passivation process to remove an interfacial charge may be efficiently performed, and the performance, stability, and reliability of a semiconductor device may be greatly improved. Furthermore, the process technology (laser annealing method) according to embodiments of the present invention may be useful in the manufacture of highly integrated semiconductor devices. By applying the laser annealing method according to embodiments of the present invention, it may be possible to manufacture semiconductor devices having high integration while having excellent performance, stability, and reliability.

This description discloses preferred embodiments of the present invention, and although certain terms are used, they are used in a general sense only to facilitate the description and understanding of the invention and are not intended to limit the scope of the invention. In addition to the embodiments disclosed herein, other modifications based on the technical ideas of the present invention are possible, as will be apparent to those of ordinary skill in the art to which the present invention belongs. One having ordinary knowledge in the art will recognize that the laser annealing method according to the embodiments described with reference to FIGS. 1a to 4 and the method of manufacturing semiconductor devices thereof may be variously substituted, altered and modified, without departing from the technical idea of the invention. Therefore, the scope of the invention is not to be defined by the embodiments described, but by the technical idea recited in the patent claims.

### INDUSTRIAL APPLICABILITY

Embodiments of the present invention may be applied to an annealing method for a workpiece and to the manufacture of a device using the method. Embodiments of the invention may be applied to laser annealing methods and the fabrication of semiconductor devices using them.

1. A method of laser annealing for a semiconductor device comprising a transistor, comprising:
preparing a semiconductor device having a transistor comprising a semiconductor and a dielectric forming a junction interface with the semiconductor; and
irradiating the semiconductor element with a laser to perform laser annealing under pressure conditions higher than 1 atmosphere in a gaseous atmosphere of at least one of deuterium (D₂), hydrogen (H₂), and ammonia (NH₃), in order to passivate interface charges between the semiconductor and the dielectric.

2. The method of claim 1, wherein the pressure condition is equal to or less than 100 atmospheres.

3. The method of claim 1, wherein the pressure condition is greater than 1 atmosphere and less than or equal to 100 atmospheres.

4. The method of claim 1,
wherein the transistor is formed on a substrate, and
wherein the laser annealing is performed while a temperature of the substrate is
controlled in a range from room temperature to 550° C.

5. The method of claim 1, wherein the laser annealing is performed in a deuterium (D₂) gas atmosphere.

6. The method of claim 1, wherein the laser annealing is performed such that a temperature of a surface portion of the semiconductor device is raised from 600 to 2000° C.

7. The method of claim 1, wherein the laser annealing is performed for 0.01 μs to 10 seconds.

8. The method of claim 1,
wherein the semiconductor comprises a channel of the transistor, and
wherein the dielectric comprises a gate dielectric layer of the transistor.

9. The method of claim 1, wherein the step of preparing the semiconductor device comprises the step of forming a wiring member electrically connected to the transistor, and
the laser annealing is performed either before or after the step of forming the wiring member.

10. The method of claim 1, wherein the laser comprises any one of ultraviolet ray, visible ray, infrared ray, and microwave.

11. A method of manufacturing a semiconductor device using the laser annealing method as recited in claim 1.
